(19) United States
(12) Patent Application Publication
(10) Pub. No.: US 2018/0247886 A1
(43) Pub. Date: Aug. 30, 2018

(54) ELECTRONIC PACKAGE STRUCTURE AND METHOD FOR MANUFACTURING THE SAME

(71) Applicant: Siliconware Precision Industries Co., Ltd., Taichung City (TW)

(72) Inventors: Chih-Hsien Chiu, Taichung City (TW); Tsung-Hsien Tsai, Taichung (TW); Hsin-Lung Chung, Taichung City (TW); Chen-Wen Huang, Taichung City (TW); Fang-Hsien Shen, Taichung City (TW)

(21) Appl. No.: 15/590,174

(22) Filed: May 9, 2017

(30) Foreign Application Priority Data
Feb. 24, 2017 (TW) 106106409

(51) Int. Cl. H01L 23/495; H01L 23/31; H01L 21/56

(52) U.S. Cl. CPC H01L 23/49568; H01L 21/56; H01L 23/3157

(57) ABSTRACT

The disclosure provides a method for manufacturing an electronic package structure, including disposing on a carrier an electronic component and a conductive frame including a plurality of conductive pads and supporting parts; and covering the electronic component and the supporting parts of the conductive frame with an encapsulating layer while allowing the conductive pads to be exposed from the encapsulating layer, thereby increasing the efficiency and reducing the cost of manufacturing processes with the design of the conductive frame. The disclosure further provides the electronic package structure as described above.

### TECHNICAL FIELD

The present disclosure is related to packaging techniques, and, more particularly, a semiconductor package and a method for manufacturing the same.

### BACKGROUND

With recent development of portable electronic products and the trends for increasingly smaller, lighter, thinner and more compact electronic products with higher density and higher performance, packaging methods such as package on package (PoP) have emerged to meet these demands.

Existing wafer packaging structures have become more complicated. When a plurality of chips are packaged onto the same electronic device, they are often stacked on top of one another, that is, at least one chip and a plurality of solder bumps (or copper balls or a hybrid structure thereof) are electrically bonded on the same surface of a substrate, and then another substrate or package structure is provided on the solder balls, thereby forming a stacked structure. The solder balls not only act as electrical contacts (I/O), but also as standoffs for the other substrate or package structure.

FIG. 1 is a schematic cross-sectional view of a conventional package stack structure 1. A semiconductor element 10 and a plurality of solder balls 13 are provided on an upper side of a package substrate 11, and an interposer 12 is stacked on top of the solder balls 13, and solder balls 17 are further provided on a lower side of the package substrate 11 for connection with another electronic device (such as a circuit board not shown). Encapsulant 14 is formed between the package substrate 11 and the interposer 12 in order to encapsulate the semiconductor element 10 and the solder balls 13.

However, in the conventional package stack structure 1, when the semiconductor element 10 on the package substrate 11 is too tall, the height of the solder balls required will need to be adjusted accordingly, and so does their volume. As such, the number of solder balls (i.e., the number of I/O) that can be placed on a unit are of the package substrate 11 is reduced.

Furthermore, electroplated copper pillars have been proposed to replace the solder balls in an attempt to address the above issue, but the electroplating process for the electroplated copper pillars is more expensive and fails to meet the demand for low cost production.

Therefore, there is an urgent need to find a solution that overcomes the aforementioned problems in the prior art.

### SUMMARY

In view of the foregoing shortcomings in the prior art, the disclosure provides an electronic package structure, which may include: a carrier; an electronic component disposed on and electrically connected with the carrier; a conductive frame including a plurality of conductive pads and a plurality of supporting parts disposed on the carrier and connected to the conductive pads; and an encapsulating layer formed on the carrier and encapsulating the electronic component and the supporting parts of the conductive frame, with the conductive pads exposed from the encapsulating layer.

The disclosure further provides a method for manufacturing an electronic package structure, which may include: disposing at least one electronic component and at least one conductive frame on a carrier, wherein the conductive frame includes a peripheral part, a plurality of connecting parts connected with the peripheral part, and a plurality of first supporting parts disposed on the carrier and connected with the connecting parts; forming on the carrier an encapsulating layer that encapsulates the electronic component and the conductive frame; and removing the peripheral part and allowing the connecting parts and the first supporting parts to remain inside the encapsulating layer.

In an embodiment, the conductive frame further includes second supporting parts connected with and supporting the peripheral part. In another embodiment, the method further includes removing the second supporting parts while removing the peripheral part.

In an embodiment, the connecting parts and the peripheral part are integrally formed.

In an embodiment, the carrier includes a first side and a second side opposite to the first side, and the electronic component is disposed on at least one of the first and second sides.

In an embodiment, the electronic component and the conductive frame are electrically connected with the carrier.

In an embodiment, a portion of a surface of the electronic component is exposed from the encapsulating layer.

In an embodiment, the connecting parts and the supporting parts are integrally formed.

In an embodiment, each of the supporting parts is bent from a corresponding one of the connecting parts by an angle.

In an embodiment, the connecting parts include a plurality of conductive pads. In another embodiment, the connecting parts further include a heat dissipating sheet, and the conductive pads are disposed around the heat dissipating sheet.

In an embodiment, before forming the encapsulating layer, a metal layer is formed on the connecting parts. In another embodiment, the metal layer is exposed from the encapsulating layer.

In summary, the electronic package structure and the method for manufacturing the same according to the disclosure include the conductive frame including the plurality of connecting parts (conductive pads) and the supporting parts on the carrier, and the connecting parts (conductive pads) are exposed from the encapsulating layer as electrical contacts (I/O) to replace traditional solder balls or copper pillars. Compared to the prior art, the manufacturing process is less time-consuming and costly.

### BRIEF DESCRIPTION OF THE DRAWINGS

FIG. 1 is a schematic cross-sectional view of a conventional package stack structure;

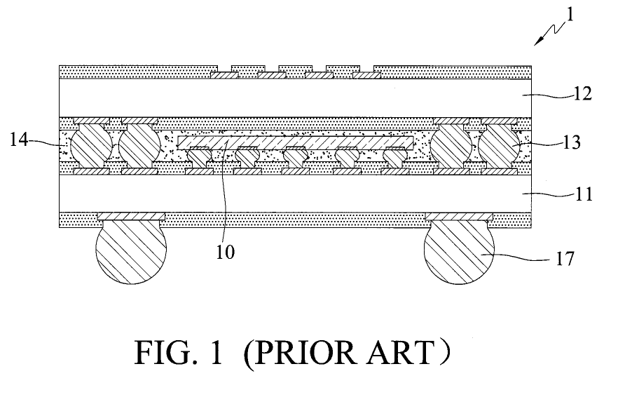

FIGS. 2A to 2D are schematic cross-sectional views illustrating a method for manufacturing an electronic package structure in accordance with a first embodiment of the disclosure;

FIGS. 2D′ and 2D″ are schematic diagrams illustrating other embodiments corresponding to FIG. 2D;

FIGS. 3A to 3C are schematic cross-sectional views illustrating a method for manufacturing an electronic package structure in accordance with a second embodiment of the disclosure; and

FIGS. 4A and 4B are schematic top views of the conductive frame of FIG. 2B in accordance with different embodiments of the disclosure.

### DETAILED DESCRIPTION OF THE EMBODIMENTS

The disclosure is described by the following specific embodiments. Those with ordinary skills in the arts can readily understand other advantages and functions of the disclosure after reading the disclosure of this specification. The present disclosure may also be practiced or applied with other different implementations. Based on different contexts and applications, the various details in this specification can be modified and changed without departing from the spirit of the present disclosure.

It should be noted that the structures, ratios, sizes shown in the drawings appended to this specification are to be construed in conjunction with the disclosure of this specification in order to facilitate understanding of those skilled in the art. They are not meant, in any ways, to limit the implementations of the disclosure, and therefore have no substantial technical meaning. Without affecting the effects created and objectives achieved by the disclosure, any modifications, changes or adjustments to the structures, ratio relationships or sizes, are to be construed as fall within the range covered by the technical contents disclosed herein. Meanwhile, terms, such as “above”, “first”, “second”, “a”, “one” and the like, are for illustrative purposes only, and are not meant to limit the range implementable by the disclosure. Any changes or adjustments made to their relative relationships, without modifying the substantial technical contents, are also to be construed as within the range implementable by the disclosure.

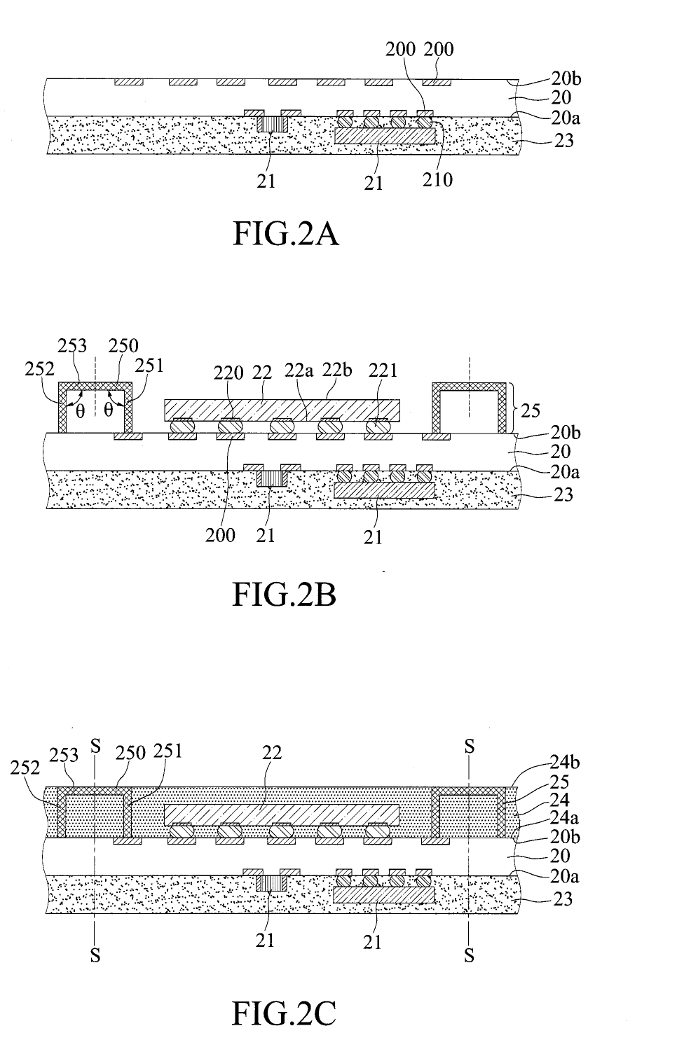

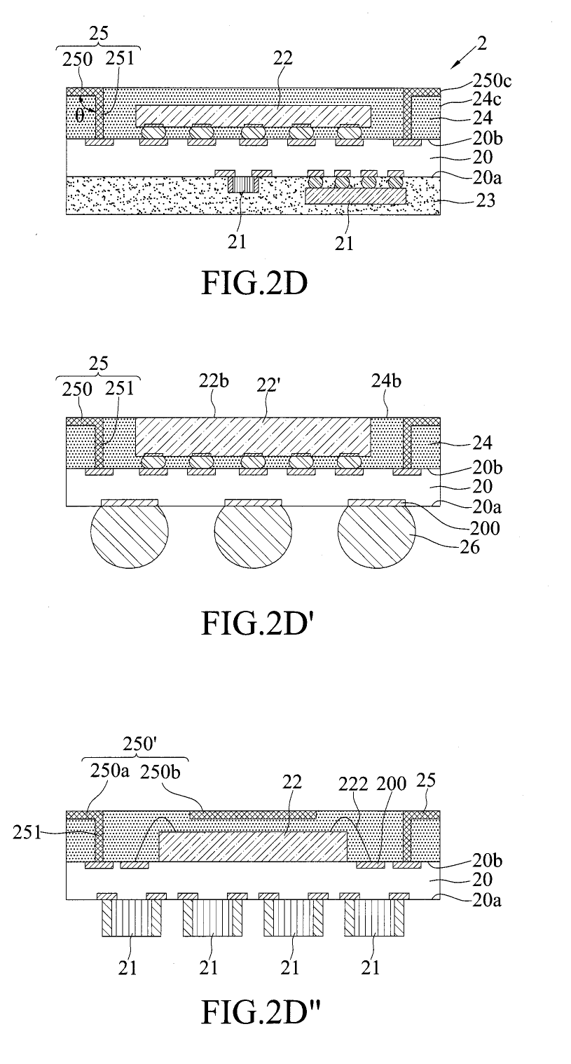

FIGS. 2A to 2D are schematic cross-sectional views illustrating a method for manufacturing an electronic package structure 2 in accordance with the disclosure. A carrier 20 is provided. At least one first electronic component 21 is optionally provided on the carrier 20. A first encapsulating layer 23 is optionally provided to encapsulate the first electronic component 21.

The carrier 20 includes a first side 20a and a second side 20b opposite to the first side 20a. In an embodiment, the carrier 20 can be a package substrate with a core layer and a wiring structure, or a coreless wiring structure that includes a plurality of wiring layers (only external wiring layers are shown, and the internal wiring layer are omitted) such as a fan out redistribution layer (RDL). It should be understood that the carrier 20 may be other types of chip carrier, such as a leadframe, an organic substrate, a silicon substrate, a ceramic substrate or other carriers with metal routing.

The first electronic component 21 is provided on the first side 20a of the carrier 20. In an embodiment, the first electronic component 21 may be an active element (such as the element with a reference number 21 on the right side of FIG. 2A), a passive element (such as the element with a reference number 21 on the left side of FIG. 2A or FIG. 2D″), or a combination thereof. The active element can be, for example, a semiconductor chip, and the passive element can be, for example, a resistor, a capacitor or an inductor. In an embodiment, the first electronic component 21 can be provided on and electrically connected to the wiring layer 200 via a plurality of conductive bumps (e.g., solder materials) in a flip-chip manner Alternatively, the first electronic component 21 can be electrically connected to the wiring layer 200 via a plurality of wires (not shown) by wire bonding or via conductive elements, such as conductive gel or solder (not shown). However, the method in which the first electronic component 21 is electrically connected to the carrier 20 is not limited as such.

The first encapsulating layer 23 is formed on the first side 20a of the carrier 20 to encapsulate the first electronic component 21. In an embodiment, the first encapsulating layer 23 can be made of, but not limited to, polyimide (PI), a dry film, an epoxy, a molding compound, or the like.

As shown in FIG. 2B, at least one second electronic component 22 and at least one conductive frame 25 that are spaced apart from each other are provided on the second side 20b of the carrier 20. The second electronic component 22 may be an active element, a passive element, or a combination thereof. In an embodiment, the active element is a semiconductor chip. In another embodiment, the passive element is a resistor, a capacitor or an inductor. In an embodiment, the second electronic component 22 has an active surface 22a and a non-active surface 22b opposite to the active surface 22a. The active surface 22a includes a plurality of electrode pads 220. The second electronic component 22 is provided on the carrier 20 in a flip-chip manner via a plurality of conductive bumps 221 (such as solder materials). In another embodiment, as shown in FIG. 2D″, the second electronic component 22 is electrically connected to the wiring layer 200 via a plurality of solder wires 222 by wire bonding. However, the method in which the second electronic component 22 is electrically connected to the carrier 20 is not limited as such.

The conductive frame 25 includes a peripheral part 253, a plurality of connecting parts 250 connected to the peripheral part 253 and protruding inwards, a plurality of first supporting parts 251 provided on the carrier 20 and connected to the connecting parts 250, and a plurality of second supporting parts 252 provided on the carrier 20 and connected to the peripheral part 253.

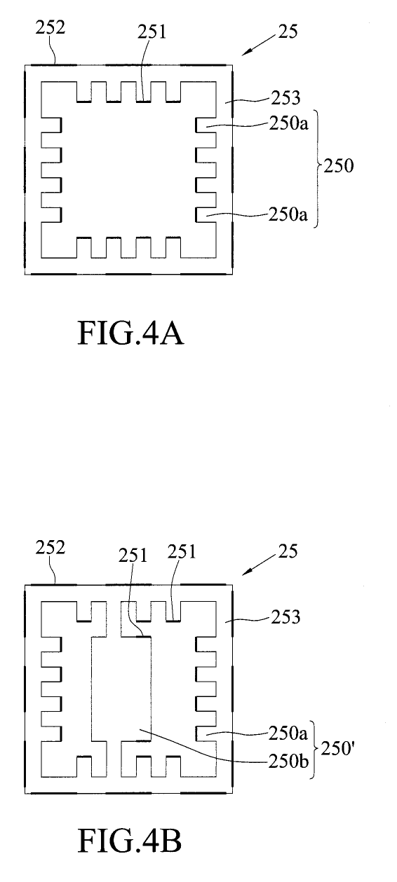

In an embodiment, as shown in FIG. 4A, the peripheral part 253, the second supporting parts 252, the first supporting parts 251 and the connecting parts 250 are integrally formed. The first supporting parts 251 are used for supporting the connecting parts 250 on the second side 20b of the carrier 20, and the second supporting parts 252 are used for supporting the peripheral part 253 on the second side 20b of the carrier 20.

In addition, as shown in FIG. 4A, the planar shape of the peripheral part 253 of the conductive frame 25 can have, for example, an enclosed shape such as a rectangle, or a non-closed shaped such as a “U-like” shape.

Moreover, as shown in FIG. 4A, the connecting parts 250 include a plurality of conductive pads 250a, or in another embodiment, as shown in FIGS. 2D″ and 4B, the connecting parts 250′ further include a heat dissipating sheet 250b connected to the peripheral part 253.

Furthermore, the first supporting parts 251 are joined onto the wiring layer 200, and the connecting parts 250 can assume any shapes as required, such as a circle, an oval or any other geometric shapes, and does not limit to the rectangle shown in FIGS. 4A and 4B.

In addition, the conductive frame 25 may be formed of a metal material, such as gold, silver, copper (Cu), nickel (Ni), iron (Fe), aluminum (Al), stainless steel (Sus) or other conductive material, and can be manufactured by punching or bending process. In an embodiment, a sheet of iron can be stamped or bent to form the peripheral part 253, the connecting parts 250, the first supporting parts 251 and the second supporting parts 252 (bold lines in FIG. 4A indicate bent places). In an embodiment, the first supporting part 251 is bent by an angle θ (e.g., about 90 degrees) from the connecting part 250; and the second supporting part 252 is also bent by about 90 degrees from the peripheral part 253, such that the cross section of the conductive frame 25 approximates the shape of an inverted U.

As shown in FIG. 2C, a second encapsulating layer 24 is formed on the second side 20b of the carrier 20 to encapsulate the second electronic component 22 and the conductive frame 25 except for the upper surfaces of the connecting parts 250 and the peripheral part 253 of the conductive frame 25 that are exposed from the second encapsulating layer 24.

The second encapsulating layer 24 includes a first surface 24a and a second surface 24b, and the first surface 24a of the second encapsulating layer 24 is combined onto the second side 20b of the carrier 20.

In an embodiment, the second encapsulating layer 24 is an insulating material, such as polyimide (PI), a dry film, an epoxy, a molding compound, or the like, and can be laminated or molded on the second side 20b of the carrier 20.

Moreover, a portion of the second surface 24b of the second encapsulating layer 24 is removed by polishing or laser, and the second surface 24b (i.e., the upper surface) of the second encapsulating layer 24 can be flush with the upper surfaces of the connecting parts 250 and the peripheral part 253. In an embodiment, the second surface 24b of the second encapsulating layer 24 is made to be flush with the surface of the conductive frame 25 while the second encapsulating layer 24 is being formed, thus without the need of removing a portion of the second surface 24b of the second encapsulating layer 24.

Furthermore, in another embodiment, the non-active surface 22b of the second electronic component 22′ can be exposed from (or flush with) the second surface 24b of the second encapsulating layer 24, such as that shown in FIG. 2D′.

In yet another embodiment, the connecting parts 250 and the peripheral part 253 are not exposed from the second encapsulating layer 24, and the conductive frame is used only as a standoff for another substrate or package structure without providing the function of an electrical contact (I/O).

As shown in FIG. 2D, the peripheral part 253 and the second supporting parts 252 are removed while the connecting parts 250 and the first supporting parts 251 are left inside the second encapsulating layer 24.

In an embodiment, singulation is performed along a cutting path S, which is the inner edge of the peripheral part 253, to obtain the electronic package structure 2, and the side faces 250c of the connecting parts 250 are exposed from the side faces 24c of the second encapsulating layer 24.

In another embodiment, as shown in FIG. 2D′, the first electronic component 21 and the first encapsulating layer 23 are omitted, and conductive elements 26 such as solder bumps are disposed on the wiring layer 200 on the first side 20a of the carrier 20. In an embodiment, as shown in FIG. 2D″, the encapsulating layer (e.g., the first encapsulating layer 23) on the first side 20a of the carrier 20 is omitted, and only the encapsulating layer (e.g., the second encapsulating layer 24) on the second side 20b of the carrier 20 is manufactured, that is, single-side molding is performed.

Therefore, the method for manufacturing the electronic package structure 2 according to the disclosure includes providing the conductive frame 25 on the carrier 20; and removing the peripheral part 253 (and the second supporting parts 252) of the conductive frame 25 to expose the connecting parts 250 (i.e., the conductive pads 250a) of the conductive frame 25 from the second encapsulating layer 24 to be used as electrical contacts (I/O). Subsequently, the first supporting parts 251 can be used as standoffs for another substrate or package structure. Compared to the use of electroplated copper pillars in the prior art, it is faster and cheaper to assemble the conductive frame 25 of the disclosure.

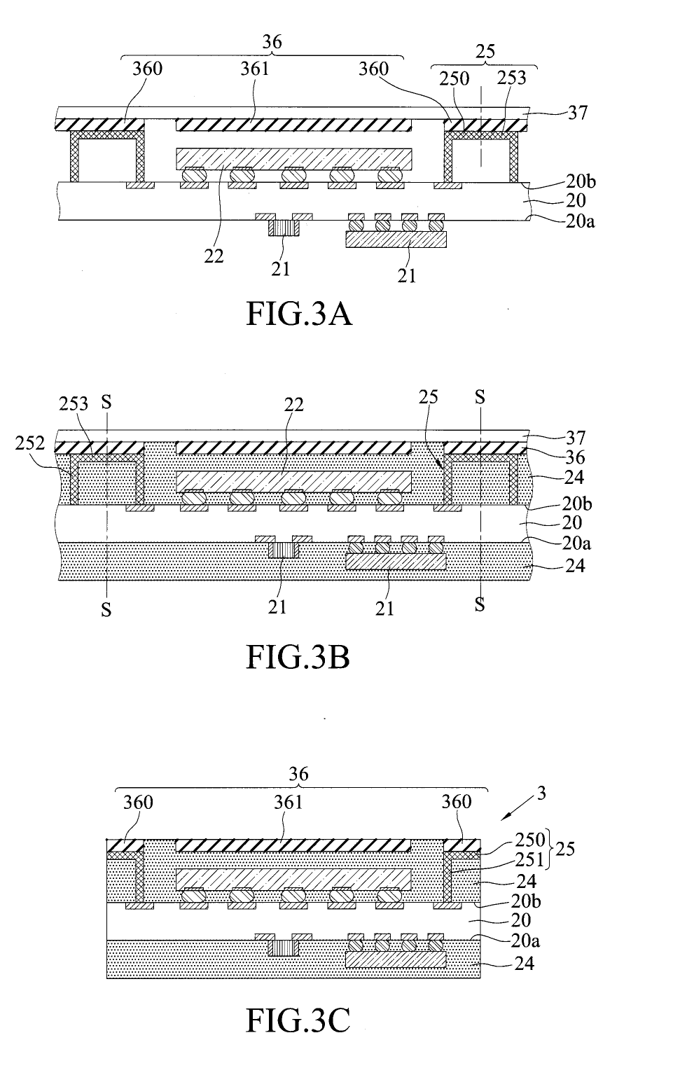

FIGS. 3A to 3C are cross sectional views of an electronic package structure 3 in accordance with a second embodiment of the disclosure. The second embodiment differs from the first embodiments in that the second embodiment further includes a metal layer.

As shown in FIG. 3A, which illustrates a step following the process of FIG. 2B, a metal layer 36 is combined with the peripheral part 253 and the connecting parts 250 of the conductive frame 25. In an embodiment, the metal layer 36 is a leadframe or a patterned wiring structure, including a plurality of separate pads 360 combined with the connecting parts 250 and the peripheral part 253, and a sheet part 361 corresponding to the location of the second electronic component 22, wherein the sheet part 361 and the pads 360 are separated, and the pads 360 surround the sheet part 361.

In an embodiment, the first encapsulating layer 23 is not formed on the first side 20a of the carrier 20.

Moreover, during the manufacturing process, the metal layer 36 is first formed on a supporting element 37, such as a tape, and then combined onto the conductive frame 25. In an embodiment, the metal layer 36 is formed on the supporting element 37 by a method such as electroplating, depositing, spin coating, or the like, or a metal layer 36 like a leadframe is formed on the supporting element 37,

Moreover, the sheet part 361 can be used as a heat dissipating sheet that can be in contact with the second electronic component 22 (not shown) or in no contact with the second electronic component 22.

In addition, the conductive frame 25 and the metal layer 36 (both are in the style of leadframes) are joined together first by a process such as punching, plating etc., and the conductive frame 25 and the metal layer 36 are both provided on the second side 20b of the carrier 20.

As shown in FIG. 3B, a second encapsulating layer 24 is formed on the first side 20a and between the second side 20b of the carrier 20 and the metal layer 36 (or the supporting layer 37), such that the second encapsulating layer 24 encapsulates the first electronic component 21, the second electronic component 22, and the conductive frame 25.

In an embodiment, during the molding process of the second encapsulating layer 24, the metal layer 36 (and the supporting element 37) will come into contact with the mold (not shown) for forming the second encapsulating layer 24, such that the metal layer 36 (and the supporting element 37) can be used as a solid flat plane for the molding process.

As shown in FIG. 3C, the supporting element 37 is first removed, and the peripheral part 253 and the second supporting parts 252 are removed by cutting along a cutting path S shown in FIG. 3B in order to leave the metal layer 36, the connecting parts 250 and the first supporting parts 251 inside the second encapsulating layer 24, while exposing the upper surface of the metal layer 36 from the second encapsulating layer 24.

In an embodiment, the upper surface of the metal layer 36 is flush with the second surface 24b of the second encapsulating layer 24. In another embodiment, after the supporting element 37 is removed, a portion of the metal layer 36 is also removed, such that the surface of the metal layer 36 is lower than the second surface 24b of the second encapsulating layer 24. It can be appreciated that while the supporting element 37 is removed, the entire metal layer 36 can be removed at the same time to expose the connecting parts 250 from the second encapsulating layer 24.

The disclosure also provides an electronic package substrate 2, 3, which includes a carrier 20, at least one first electronic component 21, at least one second electronic component 22, 22′, a conductive frame 25, and a second encapsulating layer 24,

The first and second electronic components 21, 22, 22′ are provided on the carrier 20 and electrically connected with the carrier 20.

The conductive frame 25 is provided on the carrier 20, and includes a plurality of connecting parts 250, 250′ and a plurality of first supporting part 251 provided on the carrier 20 and connected and supporting the connecting parts 250, 250′.

The second encapsulating layer 24 is formed on the carrier 20 for encapsulating the second electronic component 22 and the first supporting parts 251 of the conductive frame 25, with upper surfaces and side surfaces of the connecting parts 250, 250′ exposed from the second encapsulating layer 24.

In an embodiment, the carrier 20 includes a first side 20a and a second side 20bopposite to the first side 20a, and the first and second electronic components 21, 22, 22′ are provided on at least one of the first side 20a and the second side 20b.

In an embodiment, the second electronic component 22′ is exposed from the second encapsulating layer 24.

In an embodiment, the connecting parts 250, 250′ and the first supporting parts 251 are integrally formed.

In an embodiment, the connecting part 250, 250′ is bent from the first supporting part by an angle θ.

In an embodiment, the connecting part 250, 250′ includes a plurality of conductive pads 250a. In another embodiment, the connecting part 250′ further includes a heat dissipating sheet 250b.

In an embodiment, the electronic package structure 3 further includes a metal layer formed on the connecting parts 250 and exposed from the second encapsulating layer 24.

In conclusion, the electronic package structure and the method for manufacturing the same according to the disclosure include providing the conductive frame on the carrier, and allowing the connecting parts to be exposed from the second encapsulating layer to replace the conventional solder balls or copper pillars, thereby achieving a faster and cheaper assembly process.

The above embodiments are only used to illustrate the principles of the disclosure, and should not be construed as to limit the disclosure in any way. The above embodiments can be modified by those with ordinary skill in the art without departing from the scope of the disclosure as defined in the following appended claims.

1. An electronic package structure, comprising:
a carrier including a first side and a second side opposite to the first side;
a first electronic component disposed on and electrically connected with the first side of the carrier;
a second electronic component disposed on and electrically connected with the second side of the carrier;
a conductive frame including a plurality of conductive pads and a plurality of first supporting parts disposed on the carrier and connected to the plurality of conductive pads, wherein the plurality of conductive pads are integrated with the plurality of first supporting parts; and
a first encapsulating layer formed on the first side of the carrier and encapsulating the first electronic component and
a second encapsulating layer formed on the second side of the carrier and encapsulating the second electronic component and the plurality of first supporting parts of the conductive frame, with the plurality of conductive pads of the conductive frame exposed from the second encapsulating layer.

2. (canceled)

3. The electronic package structure of claim 1, wherein the conductive frame is electrically connected with the carrier.

4. The electronic package structure of claim 1, wherein the first electronic component or the second electronic component has a surface with a portion exposed from the first encapsulating layer or the second encapsulating layer, respectively.

5. (canceled)

6. The electronic package structure of claim 1, wherein each of the plurality of first supporting parts is bent from a corresponding one of the plurality of conductive pads by an angle.

7. The electronic package structure of claim 1, wherein the conductive frame further includes a peripheral part connected with the plurality of conductive pads and a plurality of second supporting parts connected with the peripheral part and disposed on the carrier.

8. The electronic package structure of claim 1, further comprising a heat dissipating sheet disposed on the second encapsulating layer, and the plurality of conductive pads are disposed around the heat dissipating sheet.

9. The electronic package structure of claim 1, further comprising a metal layer formed on the plurality of conductive pads and exposed from the second encapsulating layer.

10. A method for manufacturing an electronic package structure, comprising:
disposing at least one electronic component and at least one conductive frame on a carrier, wherein the at least one conductive frame includes a peripheral part, a plurality of connecting parts connected with the peripheral part, and a plurality of first supporting parts disposed on the carrier and connected with the plurality of connecting parts;
forming on the carrier an encapsulating layer for encapsulating the at least one electronic component and the at least one conductive frame; and
removing the peripheral part and allowing the plurality of connecting parts and the plurality of first supporting parts to remain inside the encapsulating layer.

11. The method of claim 10, wherein the carrier includes a first side and a second side opposite to the first side, and the at least one electronic component is disposed on at least one of the first side and the second side.

12. The method of claim 10, wherein the at least one conductive frame is electrically connected with the carrier.

13. The method of claim 10, wherein the at least one electronic component has a surface with a portion exposed from the encapsulating layer.

14. The method of claim 11, wherein the at least one conductive frame further includes a plurality of second supporting parts connected with and supporting the peripheral part.

15. The method of claim 14, further comprising removing the plurality of second supporting parts while removing the peripheral part.

16. The method of claim 10, wherein the plurality of connecting parts are integrated with the plurality of first supporting parts.

17. The method of claim 10, wherein each of the plurality of first supporting parts is bent from a corresponding one of the plurality of connecting parts by an angle.

18. The method of claim 10, wherein the plurality of connecting parts include a plurality of conductive pads disposed around a heat dissipating sheet of the plurality of connecting parts.

19. The method of claim 10, wherein forming the encapsulating layer includes forming the encapsulating layer with a metal layer formed on the plurality of connecting parts and exposed from the encapsulating layer.

20. The method of claim 10, wherein a portion of the surfaces of the plurality of connecting parts is exposed from the encapsulating layer.
